(19) United States
(12) Patent Application Publication
(10) Pub. No.: US 2024/0339496 A1
(43) Pub. Date: Oct. 10, 2024

(54) SEMICONDUCTOR DIES WITH ROUNDED OR CHAMFERED EDGES

(71) Applicant: Micron Technology, Inc., Boise, ID (US)

(72) Inventors: Quang NGUYEN, Boise, ID (US); Christopher GLANCEY, Boise, ID (US); Koustav SINHA, Boise, ID (US)

(21) Appl. No.: 18/624,811

(22) Filed: Apr. 2, 2024

Related U.S. Application Data
(60) Provisional application No. 63/494,275, filed on Apr. 5, 2023.

(51) Int. Cl. H01L 29/06; H01L 21/78; H01L 23/00; H01L 25/065; H10B 80/00

(52) U.S. Cl. CPC H01L 29/0657; H01L 21/78; H01L 24/32; H01L 25/0652; H01L 2224/32225; H10B 80/00

(57) ABSTRACT

Implementations described herein relate to various semiconductor device assemblies. In some implementations, a semiconductor die includes a first main face and an opposing second main face, the first main face and the second main face being spaced apart from one another in a direction. The semiconductor die may include a plurality of side faces disposed substantially perpendicular to the first main face and the second main face, the plurality of side faces extending between the first main face and the second main face in the direction. The semiconductor die may include one of a first rounded edge or a first chamfered edge, the one of the first rounded edge or the first chamfered edge connecting at least one side face, of the plurality of side faces, to the first main face.

### CROSS REFERENCE TO RELATED APPLICATION

This Patent Application claims priority to U.S. Provisional Patent Application No. 63/494,275, filed on Apr. 5, 2023, and entitled “SEMICONDUCTOR DIES WITH ROUNDED OR CHAMFERED EDGES.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to semiconductor dies with rounded or chamfered edges.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus associated with integrated circuits.

FIG. 2 is a diagram of an example memory device that may be associated with one or more of the semiconductor dies described herein and/or that may be manufactured using techniques described herein.

FIGS. 3A-3B are diagrams of example semiconductor packages that include semiconductor dies having chamfered edges.

FIGS. 4A-4B are diagrams of example semiconductor packages that include semiconductor dies having rounded edges.

FIGS. 5A-5K are diagrams of an example process used to fabricate a semiconductor die having a rounded or chamfered edge.

FIG. 6 is a diagram of example equipment used to manufacture various semiconductor packages, semiconductor dies, memory devices, or similar components described herein.

FIG. 7 is a flowchart of an example method of forming a semiconductor die having a rounded or chamfered edge.

FIG. 8 is a flowchart of an example method of forming an integrated assembly or memory device having a semiconductor die with a rounded or chamfered edge.

FIG. 9 is a flowchart of an example method of forming an integrated assembly or memory device having a semiconductor die with a rounded or chamfered edge.

### DETAILED DESCRIPTION

Semiconductor dies, such as memory dies, controllers, or similar dies, may be configured to attach to a substrate or similar portion of a semiconductor device assembly and/or semiconductor package. In some examples, a semiconductor die may have the shape of a rectangular prism, with a pair of opposing main faces (e.g., a pair of opposing rectangular faces) extending substantially parallel to one another, and four side faces (e.g., four rectangular faces) extending between the pair of opposing main faces and extending substantially perpendicular to the pair of opposing main faces. As used herein, “substantially parallel” means that the corresponding faces are parallel to one another (e.g., lying in corresponding planes that are in a same three-dimensional space that never meet) within reasonable tolerances of manufacturing and measurement, and “substantially perpendicular” means that the corresponding faces are perpendicular to one another (e.g., lying in corresponding planes that intersect at a right angle) within reasonable tolerances of manufacturing and measurement.

In some cases, semiconductor dies may be prone to cracking and/or delamination at certain portions of the semiconductor die. For example, in cases in which a semiconductor die has the shape of a rectangular prism, the semiconductor die may be prone to cracking and/or delamination at a die corner, which may be a portion of the die where three faces come together (e.g., where a main face meets two side faces). At such corners, the semiconductor die may experience high stress due to mechanical and/or thermal loads on the semiconductor die. The cracking and/or delamination of the semiconductor die, such as at a die corner thereof, may result in faulty performance or even complete failure of the semiconductor die.

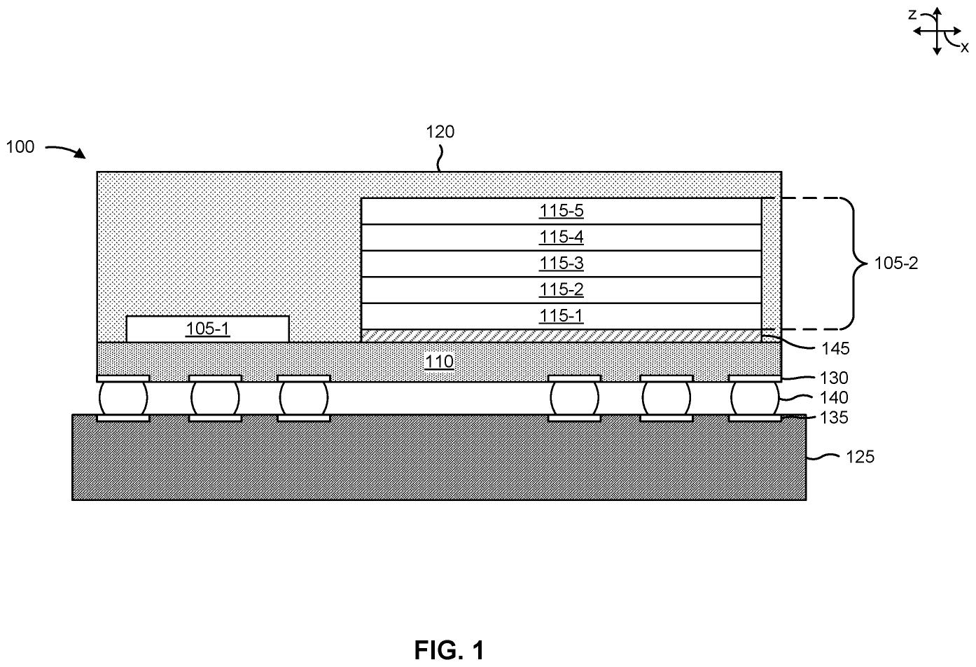

Some implementations described herein enable reduced stress concentration on a semiconductor die, thereby reducing a cracking and/or delamination risk and otherwise improving a performance of the semiconductor die. In some implementations, an edge of a semiconductor die (e.g., a bottom edge of the die) may be chamfered or rounded to reduce stress concentration at the die corners and/or other portions of the semiconductor die. In some other implementations, multiple edges of the semiconductor die may be chamfered or rounded, such as a bottom edge of the die as well as an opposing top edge of the die. In some implementations, an edge of a semiconductor die may be chamfered or rounded by using a chamfered or filleted blade during a dicing process of the semiconductor die, thereby achieving a chamfered or rounded edge without requiring additional fabrication steps as compared to fabrication of known semiconductor dies. As a result, stress concentration along edges and/or corners of a semiconductor die may be reduced, resulting in a reduced risk of die cracking and/or delamination and thus improved semiconductor die performance. These and other features of the various implementations are discussed in more detail below in connection with FIGS. 1-9.

FIG. 1 is a diagram of an example apparatus 100 associated with integrated circuits.

In FIG. 1 and the figures that follow, each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a synchronous dynamic RAM (SDRAM) device, a ferroelectric RAM (FeRAM) device, a magnetic RAM (MRAM) device, a resistive RAM (RRAM) device, a holographic RAM (HRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed proximate to the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115). In some implementations, one or more dies of the apparatus 100 may be attached to a portion of the apparatus using a die attach component. For example, as shown in FIG. 1, the base die 115-1 may be coupled to the substrate 110 via a die attach component 145. In some implementations, the die attach component 145 may be a die attach film (DAF), an underfill material (e.g., a moldable underfill (MUF) and/or a capillary underfill material), an epoxy material, a die attach paste, a die attach alloy, or a similar die attach material.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

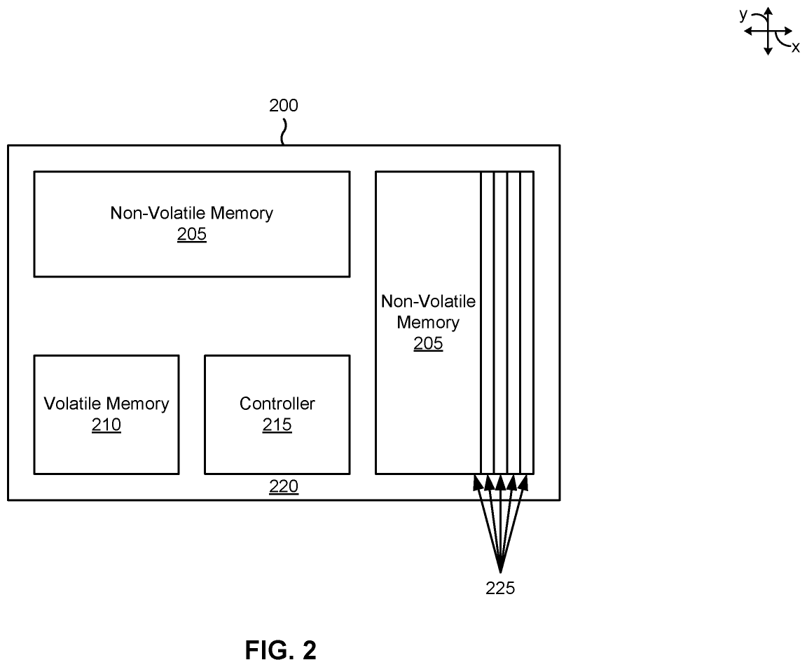

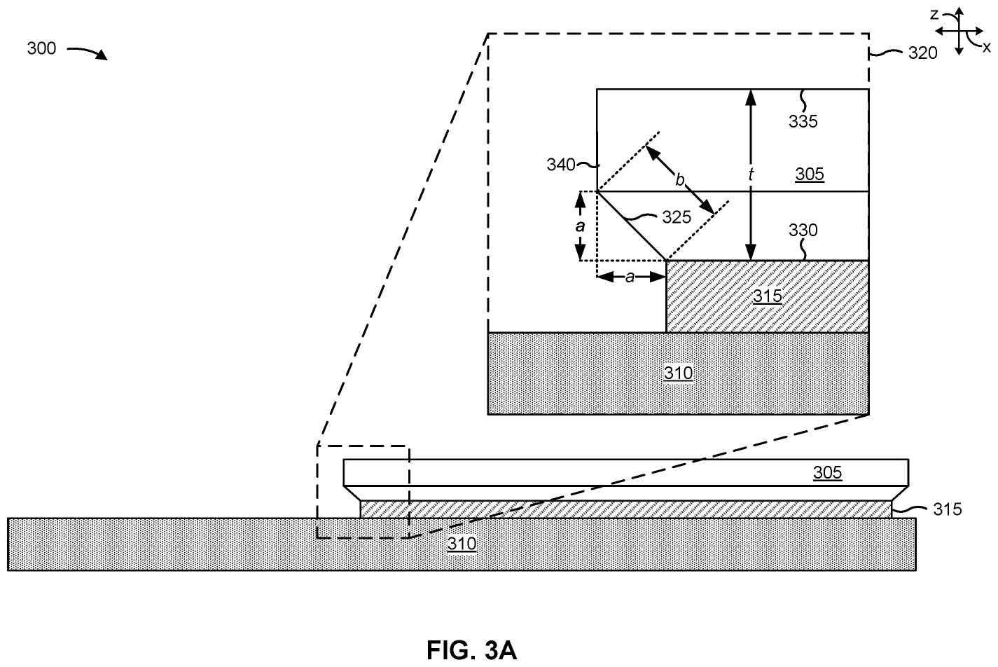

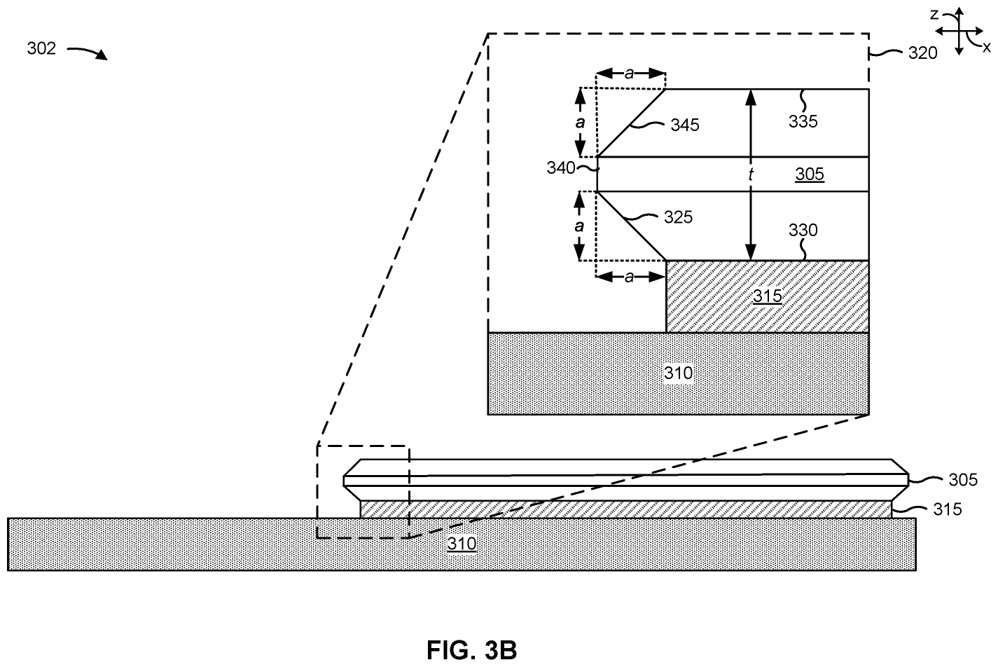

FIG. 2 is a diagram of an example memory device 200 that may be associated with one or more of the semiconductor dies described herein and/or that may be manufactured using techniques described herein. In some cases, the memory device 200 may be an example of the apparatus 100 described above in connection with FIG. 1. In some other implementations, the memory device 200 may be similar to the apparatus 100 except for the structure of one or more semiconductor dies used therein, which may take the form of one of the semiconductor dies described below in connection with FIGS. 3A-5K. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIGS. 3A-3B are diagrams of example semiconductor packages 300, 302 that include semiconductor dies having chamfered edges. More particularly, FIG. 3A shows a first example semiconductor package 300, which includes a semiconductor die 305 having a bottom chamfered edge, and FIG. 3B shows a second example semiconductor package 302, which includes the semiconductor die 305 having the bottom chamfered edge and a top chamfered edge.

As shown in FIG. 3A, the semiconductor die 305 may be coupled to a substrate 310 (e.g., substrate 110, substrate 220). In some implementations, the semiconductor die 305 may be coupled to the substrate via a die attach component 315 (e.g., die attach component 145). Moreover, as best seen in the enlarged view of the semiconductor die 305 in the dashed box indicated by reference number 320, in some implementations the semiconductor die 305 may include a chamfered edge 325. More particularly, the semiconductor die 305 may include a first main face 330 (e.g., a face of the semiconductor die 305 lying in a plane defined by x-axis and y-axis directions), an opposing second main face 335 (e.g., another face of the semiconductor die 305 lying in a plane defined by the x-axis and y-axis directions that is substantially parallel to the first main face 330), and a plurality of side faces 340 that are substantially perpendicular to the first main face and/or the second main face 335 (e.g., faces of the semiconductor die 305 lying in planes defined by in the x-axis and z-axis directions or the y-axis and z-axis directions that are substantially perpendicular to the first main face 330 and/or the second main face 335). As shown in FIG. 3A, the first main face 330 and the second main face 335 may be spaced apart in the z-axis direction, and the plurality of side faces may extend between the first main face 330 and the second main face 335 in the z-axis direction (e.g., such that an upper end of each of the plurality of side faces 340 is at or below, in the z-axis direction, the second main face 335, and such that a lower end of each of the plurality of side faces 340 is at or above, in the z-axis direction, the first main face 330). In such implementations, the chamfered edge 325 may connect at least one side face, of the plurality of side faces 340, to the first main face 330, as shown in the close-up view in FIG. 3A. In some implementations, the chamfered edge 325 may connect each of the plurality of side faces to the first main face 330 (e.g., the chamfered edge 325 may extend around an entire perimeter of the first main face 330).

In some implementations, a size of the chamfered edge 325 may be defined according to an isosceles triangle that includes a pair of legs (indicated by the dimension a in FIG. 3A, which is sometimes referred to herein as a “leg length”) and a hypotenuse that extends along a face of the chamfered edge 325 (indicated by the dimension b in FIG. 3A). In such implementations, a leg length of the chamfered edge 325 (e.g., a) may be greater than one-twentieth of the thickness of the semiconductor die 305 and less than one-half of a thickness of the semiconductor die 305, with the thickness of the semiconductor die 305 corresponding to a distance, in the z-axis direction, between the first main face 330 and the second main face 335 (indicated by the dimension t in FIG. 3A). In some aspects, including the chamfered edge 325 with such dimensions (e.g., with t/20<a<t/2) may reduce stress concentration (and thus cracking and/or delamination) at certain portions of the semiconductor die 305 as compared to a similarly sized and/or shaped semiconductor die that does not include the chamfered edge 325. For example, for semiconductor dies exposed to a 170 degree Celsius (C) to 25 degree C. thermal load, the semiconductor die 305 with the chamfered edge 325 may result in an approximately 50% reduction in stresses at a die corner as compared to a similarly sized and/or shaped semiconductor die that does not include the chamfered edge 325.

In some implementations, due to the presence of the chamfered edge 325, an outer perimeter of the semiconductor die 305 (e.g., a perimeter extending along the outermost surfaces of the semiconductor die 305 in the x-axis and y-axis directions, which may correspond to the plurality of side faces 340) may extend beyond (e.g., may be larger than) an outer perimeter of the first main face 330 and/or the perimeter of the die attach component 315 disposed at the first main face 330, as shown in FIG. 3A. Put another way, in implementations in which the semiconductor die 305 is attached to the substrate 310 via the die attach component 315, the chamfered edge 325 may extend, in an x-axis direction and/or a y-axis direction, beyond an outer perimeter of the die attach component 315 and/or an outer perimeter of the first main face 330 (e.g., the semiconductor die 305 may overhang the die attach component 315). Additionally, or alternatively, in some implementations, the chamfered edge 325 is disposed proximate to an outer edge of the die attach component 315, as best seen in the close-up view in FIG. 3A. In some implementations, extending the outer perimeter of the semiconductor die 305 beyond an outer perimeter of the first main face 330 and/or the die attach component 315 may increase heat dissipation and thermal performance of the semiconductor die 305, thereby further improving performance and longevity of the semiconductor die 305.

Although the semiconductor die 305 shown in FIG. 3A includes one chamfered edge 325 (e.g., a bottom chamfered edge), in some other implementations, the semiconductor die 305 may include more than one chamfered edge. For example, as shown in FIG. 3B, in some implementations the semiconductor die 305 may include a bottom chamfered edge (e.g., chamfered edge 325) and a top chamfered edge (e.g., chamfered edge 345). Put another way, in some implementations the semiconductor die 305 may further include a second chamfered edge 345 that connects at least one side face, of the plurality of side faces 340, to the second main face 335. In some implementations, the second chamfered edge 345 may connect each of the plurality of side faces 340 to the second main face 335 (e.g., the second chamfered edge 345 may extend around an entire perimeter of the second main face 335) in a similar manner as described above in connection with the chamfered edge 325 and the first main face 330.

Additionally, or alternatively, in some implementations, the second chamfered edge 345 may be similarly sized and/or shaped as the chamfered edge 325. For example, in some implementations, a leg length of the second chamfered edge 345 (e.g., a) may be greater than one-twentieth of the thickness of the semiconductor die 305 and less than one-half of a thickness of the semiconductor die 305 (e.g., t/20<a<t/2). In some implementations, including the second chamfered edge 345 may further reduce stress concentration (and thus cracking and/or delamination) at certain portions of the semiconductor die 305 as compared to a similarly sized and/or shaped semiconductor die that does not include the second chamfered edge 345, and/or including the second chamfered edge 345 may further improve heat dissipation and/or otherwise increase a thermal performance of the semiconductor die 305 as compared to a similarly sized and/or shaped semiconductor die that does not include the second chamfered edge 345.

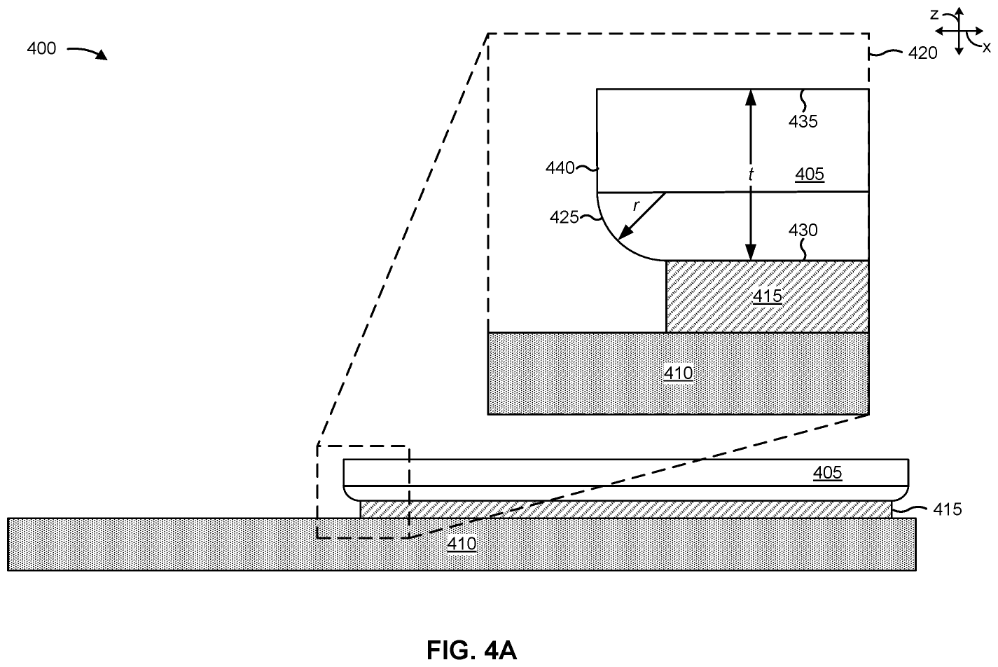

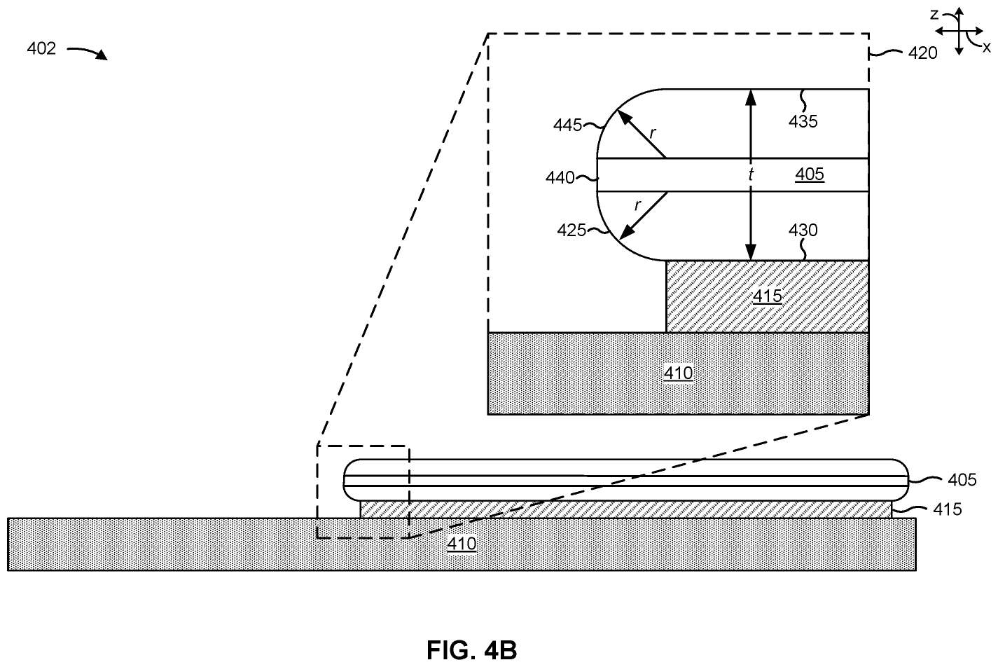

Although the implementations shown in connection with FIGS. 3A and 3B include a semiconductor die 305 having chamfered edges, in some other implementations a semiconductor die may include a differently shaped edge. For example, a semiconductor die may include one or more rounded edges in order to reduce stress concentration on the semiconductor die and/or otherwise reduce a cracking or delamination risk associated with the die, which is described in more detail below in connection with FIGS. 4A-4B.

As indicated above, FIGS. 3A-3B are provided as examples. Other examples may differ from what is described with respect to FIGS. 3A-3B.

FIGS. 4A-4B are diagrams of example semiconductor packages 400, 402 that include semiconductor dies having rounded edges. More particularly, FIG. 4A shows a first example semiconductor package 400, which includes a semiconductor die 405 having a bottom rounded edge, and FIG. 4B a second example semiconductor package 402, which includes the semiconductor die 405 having the bottom rounded edge and a top rounded edge.

As shown in FIG. 4A, the semiconductor die 405 may be coupled to a substrate 410 (e.g., substrate 110, substrate 220, substrate 310). In some implementations, the semiconductor die 405 may be coupled to the substrate via a die attach component 415 (e.g., die attach component 145, die attach component 315). Moreover, as best seen in the enlarged view of the semiconductor die 405 in the dashed box indicated by reference number 420, in some implementations the semiconductor die 405 may include a rounded edge 425. More particularly, the semiconductor die 405 may include a first main face 430 (e.g., a face of the semiconductor die 405 lying in a plane defined by the x-axis and y-axis directions, which may be substantially similar to the first main face 330), an opposing second main face 435 (e.g., another face of the semiconductor die 405 lying in a plane defined by the x-axis and y-axis directions that is substantially parallel to the first main face 430, which may be substantially similar to the second main face 335), and a plurality of side faces 440 that are substantially perpendicular to the first main face 430 and/or the second main face 435 (e.g., faces of the semiconductor die 405 lying in planes defined by the x-axis and z-axis directions or the y-axis and z-axis directions, which may be substantially similar to the plurality of side faces 340). As shown in FIG. 4A, the first main face 430 and the second main face 435 may be spaced apart in the z-axis direction, and the plurality of side faces 440 may extend between the first main face 430 and the second main face 435 in the z-axis direction (e.g., such that an upper end of each of the plurality of side faces 440 is at or below, in the z-axis direction, the second main face 435, and such that a lower end of each of the plurality of side faces 440 is at or above, in the z-axis direction, the first main face 430). In such implementations, the rounded edge 425 may connect at least one side face, of the plurality of side faces 440, to the first main face 430, as shown in the close-up view in FIG. 4A. In some implementations, the rounded edge 425 may connect each of the plurality of side faces 440 to the first main face 430 (e.g., the rounded edge 425 may extend around an entire perimeter of the first main face 430).

In some implementations, a radius of curvature of the rounded edge 425 (indicated by the dimension r in FIG. 4A) may be greater than one-twentieth of the thickness of the semiconductor die 405 and less than one-half of a thickness of the semiconductor die 405 (e.g., t). In some implementations, including the rounded edge 425 with such dimensions (e.g., with t/20<r<t/2) may reduce stress concentration (and thus cracking and/or delamination) at certain portions of the semiconductor die 405 as compared to a similarly sized and/or shaped semiconductor die that does not include the rounded edge 425. For example, for semiconductor dies exposed to a 170 degree C. to 25 degree C. thermal load, the semiconductor die 405 with the rounded edge 425 may result in an approximately 50% reduction in stresses at a die corner as compared to a similarly sized and/or shaped semiconductor die that does not include the rounded edge 425.

In some implementations, due to the presence of the rounded edge 425, an outer perimeter of the semiconductor die 405 (e.g., a perimeter extending along the outermost surfaces of the semiconductor die 405 in the x-axis and y-axis directions, which may correspond to the plurality of side faces 440) may extend beyond (e.g., may be larger than) an outer perimeter of the first main face 430 and/or the die attach component 415 disposed at the first main face 430, as shown in FIG. 4A. Put another way, in implementations in which the semiconductor die 405 is attached to the substrate 410 via the die attach component 415, the rounded edge 425 may extend, in an x-axis direction and/or a y-axis, beyond an outer perimeter of the die attach component 415 and/or an outer perimeter of the first main face 430 (e.g., the semiconductor die 405 may overhang the die attach component 415). Additionally, or alternatively, in some implementations, the rounded edge 425 may be proximate to an outer edge of the die attach component 415, as best seen in the close-up view in FIG. 4A. In some implementations, extending the outer perimeter of the semiconductor die 405 beyond an outer perimeter of the first main face 430 and/or the die attach component 415 may increase heat dissipation and thermal performance of the semiconductor die 405, thereby further improving performance and longevity of the semiconductor die 405.

Although the semiconductor die 405 shown in FIG. 4A includes one rounded edge 425 (e.g., a bottom rounded edge), in some other implementations, the semiconductor die 405 may include more than one rounded edge. For example, as shown in FIG. 4B, in some implementations the semiconductor die 405 may include a bottom rounded edge (e.g., rounded edge 425) and a top rounded edge (e.g., rounded edge 445). Put another way, in some implementations the semiconductor die 405 may further include a second rounded edge 445 that connects at least one side face, of the plurality of side faces 440, to the second main face 435. In some implementations, the second rounded edge 445 may connect each of the plurality of side faces 440 to the second main face 435 (e.g., the second rounded edge 445 may extend around an entire perimeter of the second main face 435) in a similar manner as described above in connection with the rounded edge 425 and the first main face 430.

Additionally, or alternatively, in some implementations, the second rounded edge 445 may be similarly sized and/or shaped as the rounded edge 425. For example, in some implementations, a radius of curvature of the second rounded edge 445 (e.g., r) may be greater than one-twentieth of the thickness of the semiconductor die 405 and less than one-half of a thickness of the semiconductor die 405 (e.g., t/20<r<t/2). In some implementations, including the second rounded edge 445 may further reduce stress concentration (and thus cracking and/or delamination) at certain portions of the semiconductor die 405 as compared to a similarly sized and/or shaped semiconductor die that does not include the second rounded edge 445, and/or including the second rounded edge 445 may further improve heat dissipation and/or otherwise increase a thermal performance of the semiconductor die 405 as compared to a similarly sized and/or shaped semiconductor die that does not include the second rounded edge 445.

As indicated above, FIGS. 4A-4B are provided as examples. Other examples may differ from what is described with respect to FIGS. 4A-4B.

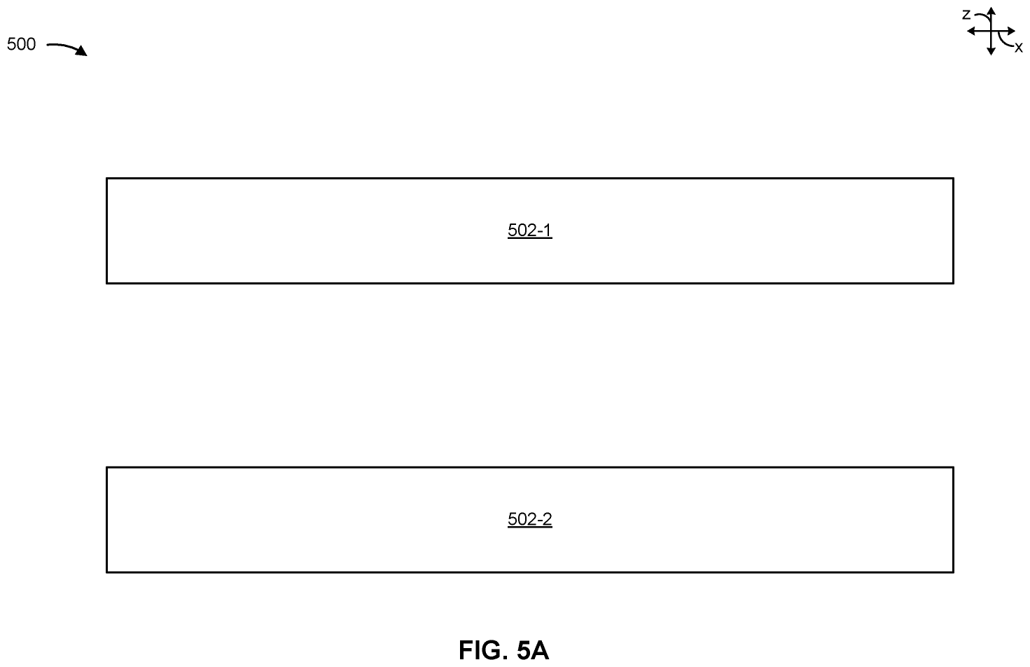

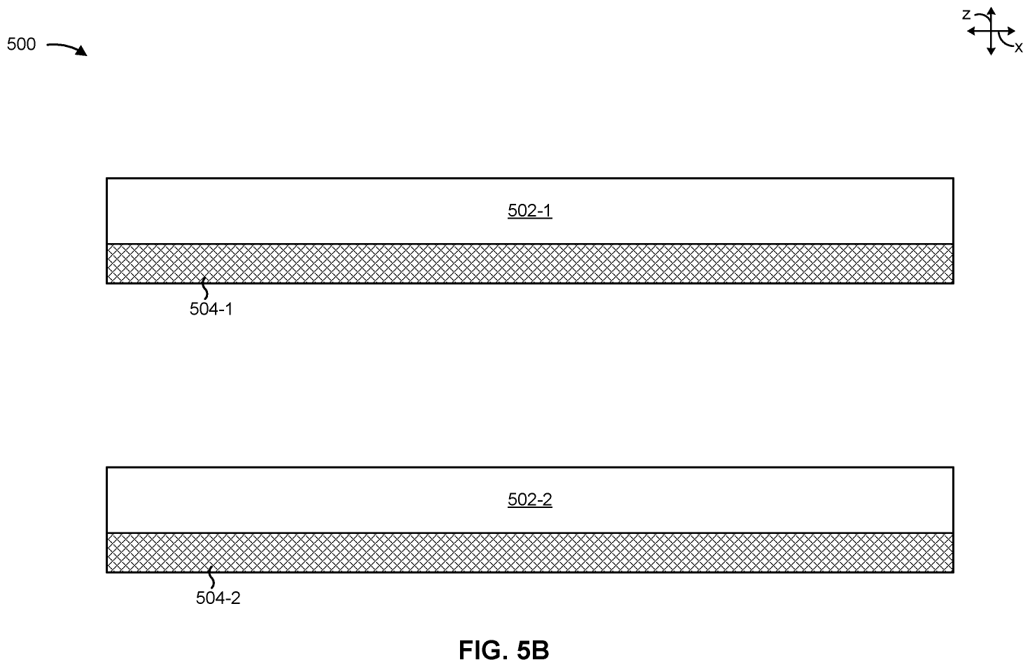

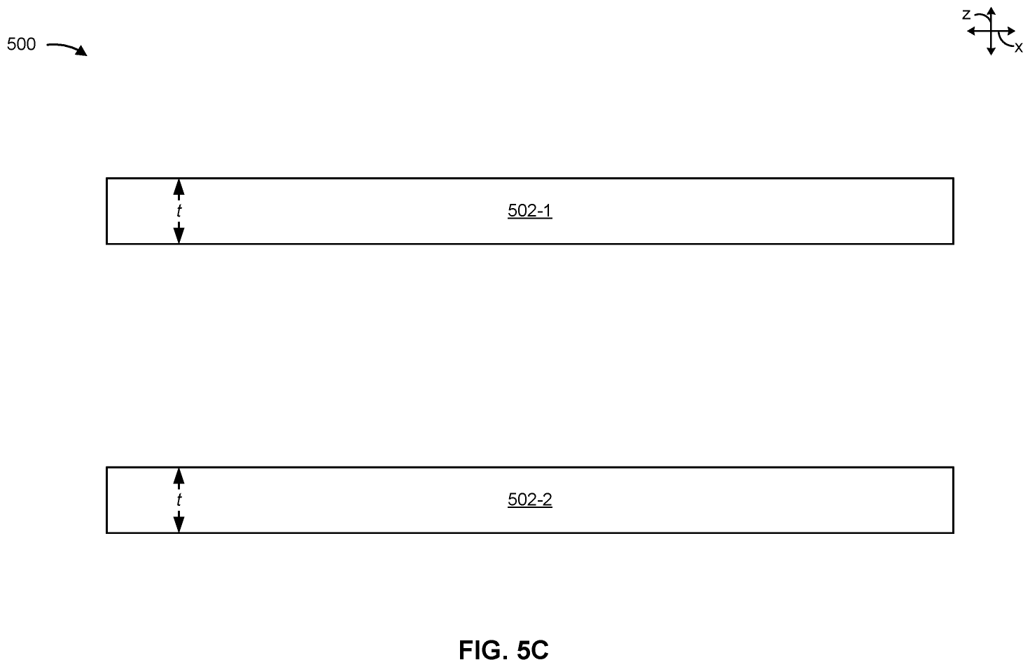

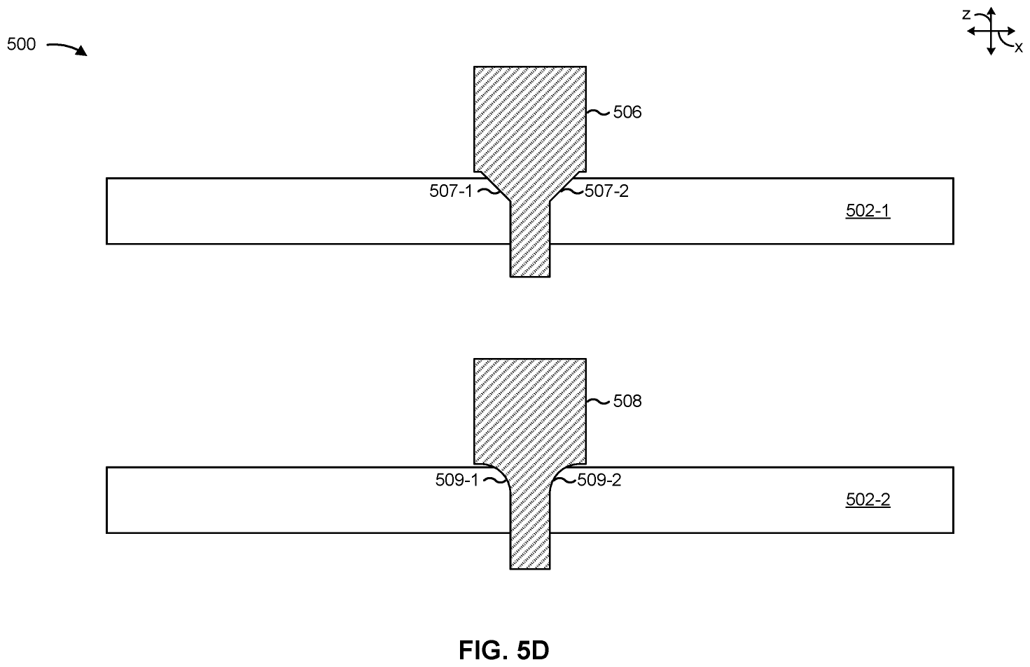

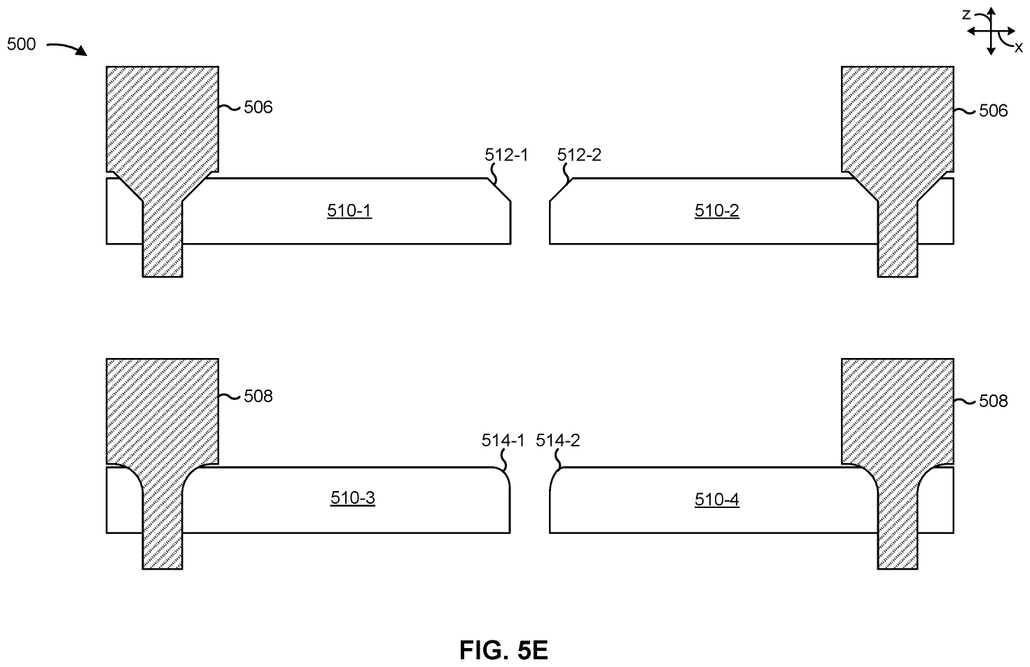

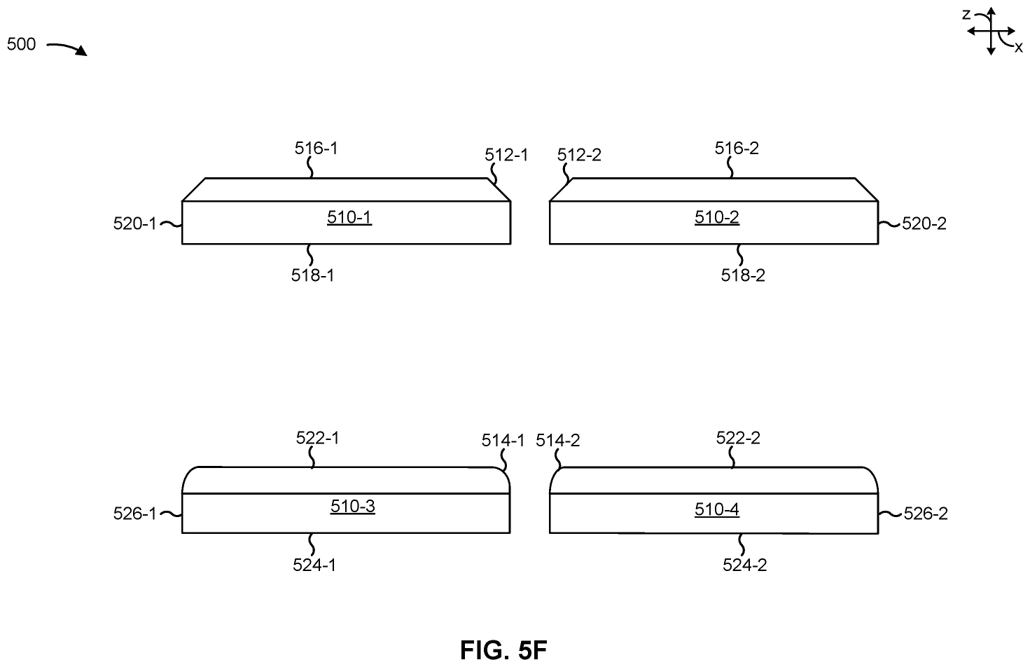

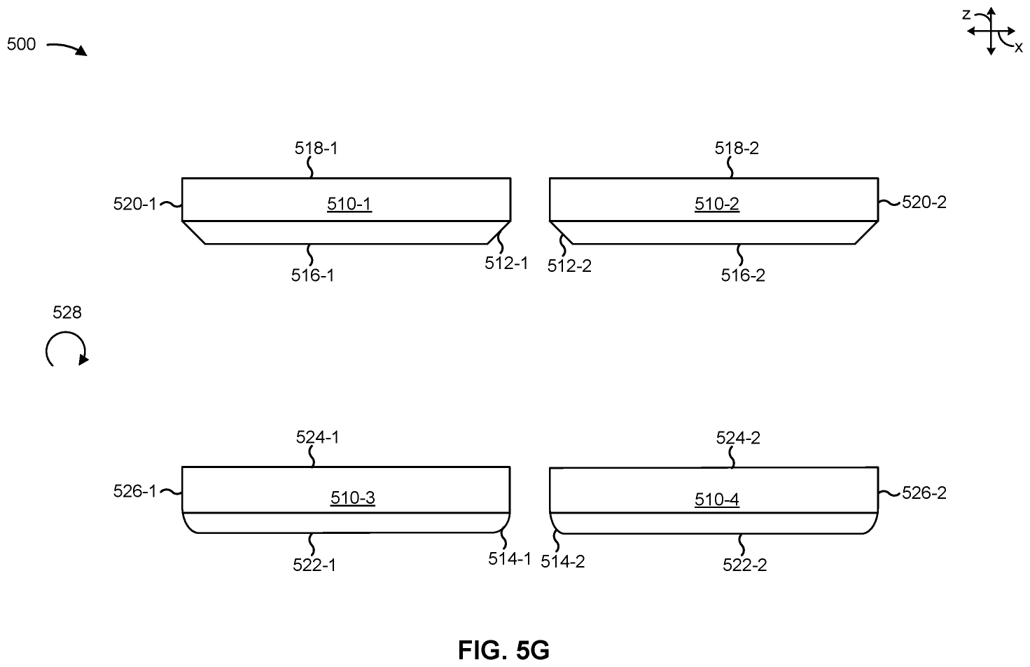

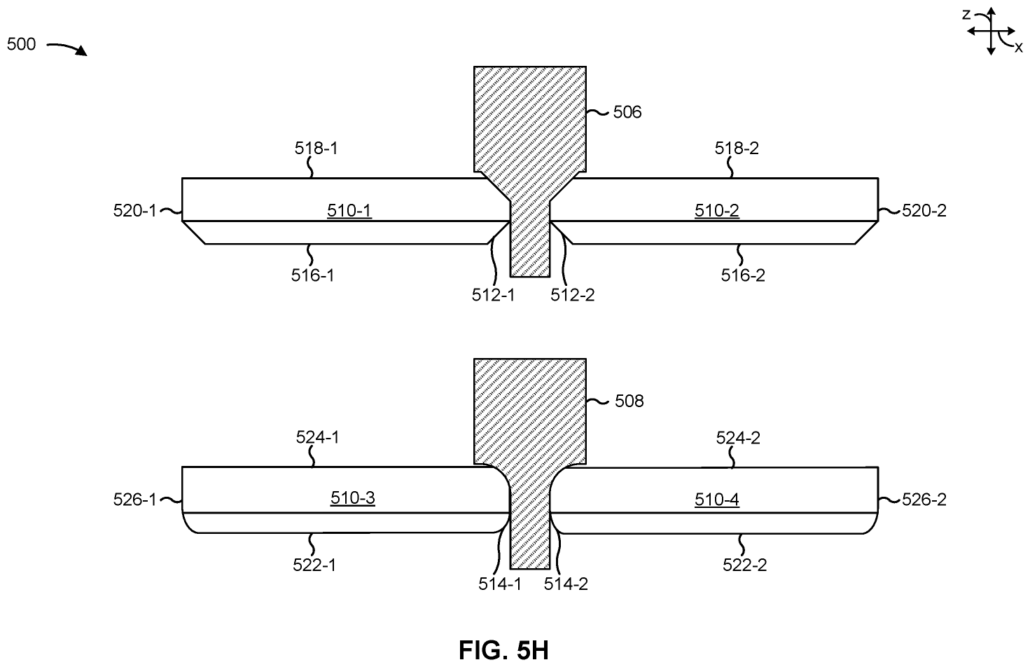

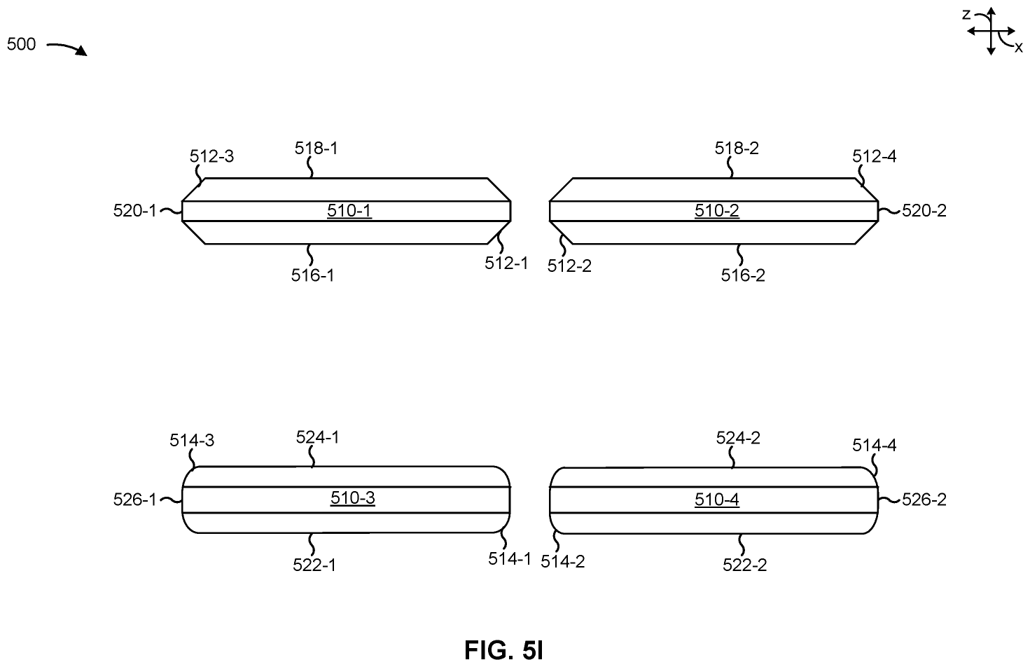

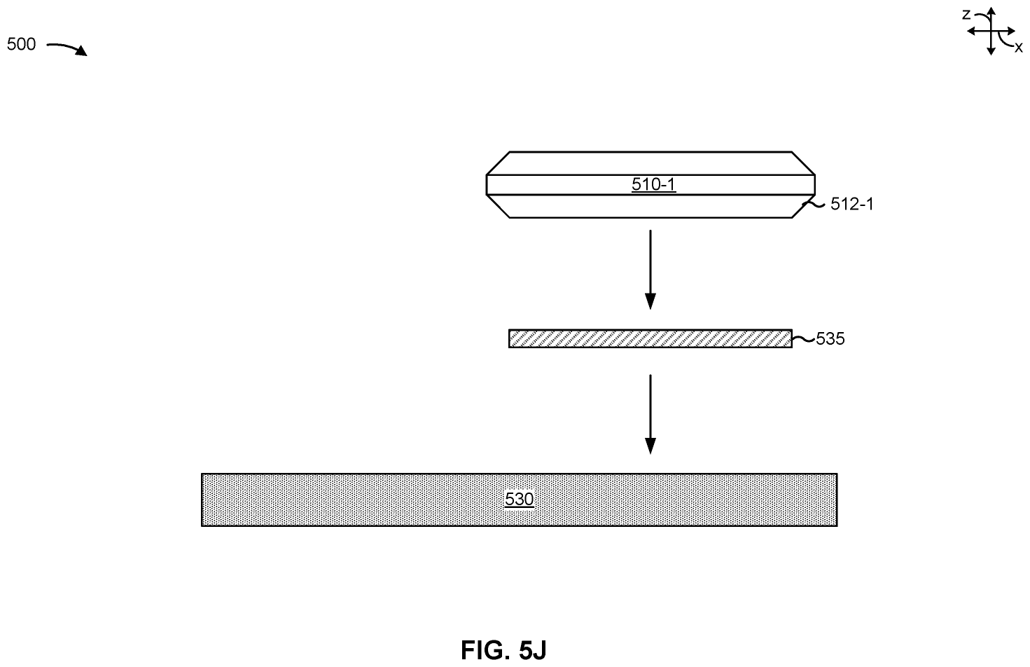

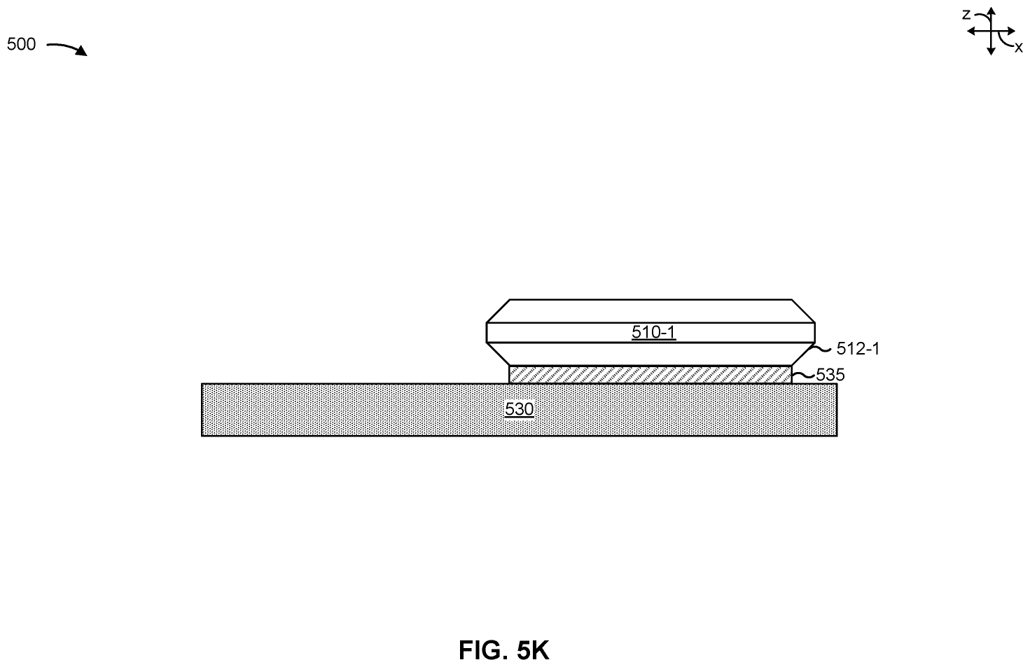

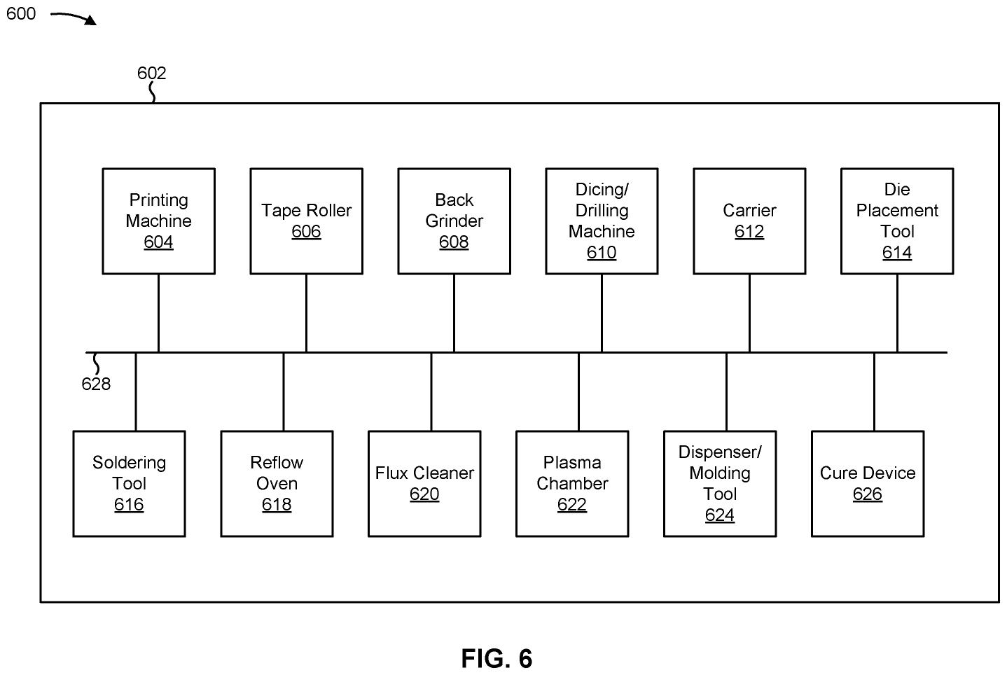

FIGS. 5A-5K are diagrams of an example process 500 used to fabricate a semiconductor die having a rounded or chamfered edge. More particularly, FIGS. 5A-5K are diagrams of an example process used to fabricate one of the semiconductor dies 305 described above in connection with FIGS. 3A-3B and/or one of the semiconductor dies 405 described above in connection with FIGS. 4A-4B. The fabrication process shown and described in connection with FIGS. 5A-5K may be performed using various semiconductor manufacturing equipment, such as the semiconductor manufacturing equipment described below in connection with FIG. 6.

As shown in FIG. 5A, the process 500 may include forming one or more semiconductor wafers 502 (shown in FIG. 5A as a first semiconductor wafer 502-1, which will be used to describe implementations associated with chamfered edges, and a second semiconductor wafer 502-2, which will be used to describe implementations associated with rounded edges). As shown in FIG. 5B, the process 500 may include removing a portion 504 of the semiconductor wafer 502 (shown as a first portion 504-1 in connection with the first semiconductor wafer 502-1 and a second portion 504-2 in connection with the second semiconductor wafer 502-2). For example, the semiconductor wafer 502 may undergo a back grinding process (sometimes referred to as a wafer lapping process, a back finishing process, or a wafer thinning process) to remove the portion 504 so that the semiconductor wafer 502 reaches a desired thickness (e.g., t as described above in connection with FIGS. 3A-4B). Put another way, the process 500 may include grinding a backside of the semiconductor wafer 502 until the semiconductor wafer 502 is a thickness (e.g., t), as shown in FIG. 5C.

In some implementations, prior to back grinding, the semiconductor wafer 502 may be laminated with a back grinding tape, such as a pressure sensitive adhesive back grinding tape, an ultraviolet (UV) curable back grinding tape, or a similar back grinding tape. For example, the back grinding tape may be laminated on a side of the semiconductor wafer 502 that includes circuit elements, such as bond pads, bumps, or other electrical contacts. The back grinding tape may protect the circuit components during the back grinding process, ensure against semiconductor wafer 502 surface damage during the back grinding process, and/or prevent semiconductor wafer 502 surface contamination caused by infiltration of grinding fluid and/or other contaminants during the back grinding process.

As shown in FIG. 5D, the process 500 may include dicing the semiconductor wafer 502 into a plurality of semiconductor dies 510 (shown in FIG. 5E) using one of a chamfered dicing blade 506 or a filleted dicing blade 508. More particularly, in the example shown in FIG. 5D, the first semiconductor wafer 502-1 may be diced using a chamfered dicing blade 506, which may be a blade and/or a saw having two chamfered surfaces 507 (shown in FIG. 5D as a first chamfered surface 507-1 and a second chamfered surface 507-2) on a cutting surface thereof. Similarly, the second semiconductor wafer 502-2 may be diced using a filleted dicing blade 508, which may be a blade and/or a saw having two filleted surfaces 509 (shown in FIG. 5D as a first filleted surface 509-1 and a second filleted surface 509-2) on a cutting surface thereof.

In this regard, as shown in FIG. 5E, the chamfered dicing blade 506 may result in semiconductor dies 510 diced from the semiconductor wafer 502 that include chamfered edges 512 (corresponding to the chamfered surfaces 507 of the chamfered dicing blade 506), and the filleted dicing blade 508 may result in semiconductor dies 510 diced from the semiconductor wafer 502 that include rounded edges 514 (corresponding to the filleted surfaces 509 of the filleted dicing blade 508). More particularly, dicing the first semiconductor wafer 502-1 using the chamfered dicing blade 506 may result in two semiconductor dies 510 (shown as a first semiconductor die 510-1 and a second semiconductor die 510-2 in FIG. 5E), with each of the semiconductor dies 510 including a corresponding chamfered edge 512 (shown as a first chamfered edge 512-1 in connection with the first semiconductor die 510-1 and a second chamfered edge 512-2 in connection with the second semiconductor die 510-2). Similarly, dicing the second semiconductor wafer 502-2 with the filleted dicing blade 508 may result in two semiconductor dies 510 (shown as a third semiconductor die 510-3 and a fourth semiconductor die 510-4 in FIG. 5E), with each of the semiconductor dies 510 including a corresponding rounded edge 514 (shown as a first rounded edge 514-1 in connection with the third semiconductor die 510-3 and a second rounded edge 514-2 in connection with the fourth semiconductor die 510-4).

As further shown in FIG. 5E, process 500 may continue a dicing step until each semiconductor die 510 is fully diced from the corresponding semiconductor wafer 502. In that regard, process 500 may include performing, for each semiconductor die 510, two cuts in the x-axis direction and two cuts in the y-axis direction (corresponding to the four side faces of the semiconductor die 510), thereby fully dicing the semiconductor die 510 from the semiconductor wafer 502. As shown in FIG. 5F, once each semiconductor die 510 is fully diced from the semiconductor wafer 502 using one of the chamfered dicing blade 506 or the filleted dicing blade 508, each semiconductor die 510 may include one of a chamfered edge 512 or a rounded edge 514 connecting a plurality of side faces of the semiconductor die 510 (e.g., side faces 340, side faces 440) to a first main face of the semiconductor die 510 (e.g., first main face 330, first main face 430).

More particularly, with respect to the first semiconductor die 510-1 and the second semiconductor die 510-2 (e.g., the semiconductor dies 510 diced using the chamfered dicing blade 506), the semiconductor dies 510 include a first main face 516 (shown as a first first main face 516-1 in connection with the first semiconductor die 510-1 and as a second first main face 516-2 in connection with the second semiconductor die 510-2), a second main face 518 (shown as a first second main face 518-1 in connection with the first semiconductor die 510-1 and as a second second main face 518-2 in connection with the second semiconductor die 510-2), a plurality of side faces 520 (shown as a first plurality of side faces 520-1 in connection with the first semiconductor die 510-1 and as a second plurality of side faces 520-2 in connection with the second semiconductor die 510-2), and a chamfered edge 512 connecting the plurality of side faces 520 to the first main face 516 (e.g., first chamfered edge 512-1 and second chamfered edge 512-2). In this regard, the first chamfered edge 512-1 and the second chamfered edge 512-2 may extend around an entire perimeter of a corresponding semiconductor die 510 and/or first main face 516, as described above in connection with FIGS. 3A-3B. Additionally, or alternatively, dicing the semiconductor wafer 502 into the plurality of semiconductor dies 510 using the chamfered dicing blade 506 may result in each semiconductor die 510 including a chamfered edge 512 having a leg length (e.g., a) greater than one-twentieth of the thickness (e.g., t) of the semiconductor die 510 and less than one-half of the thickness of the semiconductor die 510 (e.g., t/20<a<t/2), as described above in connection with FIGS. 3A-3B.

Similarly, with respect to the third semiconductor die 510-3 and the fourth semiconductor die 510-4 (e.g., the semiconductor dies 510 diced using the filleted dicing blade 508), the semiconductor dies 510 include a first main face 522 (shown as a first first main face 522-1 in connection with the third semiconductor die 510-3 and as a second first main face 522-2 in connection with the fourth semiconductor die 510-4), a second main face 524 (shown as a first second main face 524-1 in connection with the third semiconductor die 510-3 and as a second second main face 524-2 in connection with the fourth semiconductor die 510-4), a plurality of side faces 526 (shown as a first plurality of side faces 526-1 in connection with the third semiconductor die 510-3 and as a second plurality of side faces 526-2 in connection with the fourth semiconductor die 510-4), and a rounded edge 514 connecting the plurality of side faces 526 to the first main face 522 (e.g., first rounded edge 514-1 and second rounded edge 514-2). In this regard, the first rounded edge 514-1 and the second rounded edge 514-2 may extend around an entire perimeter of a corresponding semiconductor die 510 and/or first main face 522, as described above in connection with FIGS. 4A-4B. Additionally, or alternatively, dicing the semiconductor wafer 502 into the plurality of semiconductor dies 510 using the filleted dicing blade 508 may result in each semiconductor die 510 including a rounded edge 514 having a radius of curvature (e.g., r) that is greater than one-twentieth of the thickness (e.g., t) of the semiconductor die 510 and less than one-half of the thickness of the semiconductor die 510 (e.g., t/20<r<t/2), as described above in connection with FIGS. 4A-4B.

As described above in connection with FIG. 3B and FIG. 4B, in some implementations a semiconductor die 510 may include two chamfered or rounded edges, including one chamfered and/or rounded edge at a top surface of the die and one chamfered and/or rounded edge at a bottom surface of the die. In such implementations, the process 500 may further include forming another chamfered or rounded edge on each semiconductor die 510. In such implementations, and as indicated by reference number 528 in FIG. 5G, the process 500 may include flipping the semiconductor dies 510 and/or the tooling (e.g., the chamfered dicing blade 506 and/or the filleted dicing blade 508) such that a chamfered edge and/or a rounded edge may be formed proximate to the second main faces 518, 524. More particularly, although for ease of discussion the semiconductor dies 510 are shown as being flipped in FIG. 5G such that the second main faces 518, 524 are facing upward, in the z-axis direction, in some other implementations, the semiconductor dies 510 may be retained in a similar orientation as shown in FIG. 5F, and tooling (e.g., the chamfered dicing blade 506, the filleted dicing blade 508, or a similar tooling) may be reoriented in order to form a chamfered edge and/or a rounded proximate to the second main faces 518, 524

As shown in FIG. 5H, process 500 may include forming (e.g., using the chamfered dicing blade 506 and/or the filleted dicing blade 508), for each semiconductor die 510, one of a second chamfered edge 512 or a second rounded edge 514 connecting at least one side face to a second main face 518, 524 of the semiconductor die 510. More particularly, as shown in FIG. 5I, and with respect to the first semiconductor die 510-1 and the second semiconductor die 510-2, the process 500 may include forming a chamfered edge 512 (shown as a third chamfered edge 512-3 in connection with the first semiconductor die 510-1 and as a fourth chamfered edge 512-4 in connection with the second semiconductor die 510-2) connecting at least one side face (e.g., at least one of the plurality of side faces 520) to a second main face 518 (e.g., the first second main face 518-1 and the second second main face 518-2) of the corresponding semiconductor die 510. With respect to the third semiconductor die 510-3 and the fourth semiconductor die 510-4, the process 500 may include forming a rounded edge 514 (shown as a third rounded edge 514-3 in connection with the third semiconductor die 510-3 and as a fourth rounded edge 514-4 in connection with the fourth semiconductor die 510-4) connecting at least one side face (e.g., at least one of the plurality of side faces 526) to a second main face 524 (e.g., the first second main face 524-1 and the second second main face 524-2) of the corresponding semiconductor die 510.

In some implementations, forming the second chamfered edge 512 and/or the second rounded edge 514 in a semiconductor die 510 may be performed using the chamfered dicing blade 506 or the filleted dicing blade 508, as shown in FIG. 5H. In some other implementations, different tooling (e.g., tooling other than the chamfered dicing blade 506 or the filleted dicing blade 508) may be used to form the second chamfered edge 512 and/or the second rounded edge 514 in a semiconductor die 510. For example, a grinding tool or similar tool may be used to grind the second chamfered edge 512 and/or the second rounded edge 514 into a semiconductor die 510.

In some implementations, process 500 may further include mounting a semiconductor die 510 having one or more chamfered and/or rounded edges to a substrate in order to form at least a portion of a semiconductor package and/or semiconductor device assembly (e.g., to form memory device 200 or a similar semiconductor device assembly). More particularly, as shown in FIG. 5J, the process 500 may include receiving a semiconductor die 510 (e.g., the first semiconductor die 510-1 as shown in FIG. 5J, but which could be any of the semiconductor dies described herein), receiving a substrate 530 (e.g., substrate 310, substrate 410), and receiving a die attach component 535 (e.g., die attach component 315, die attach component 415). As shown in 5K, the process 500 may further include coupling the semiconductor die 510 to the substrate 530 via the die attach component 535 such that the first rounded edge or the first chamfered edge (e.g., the first chamfered edge 512-1 in the example shown in FIG. 5K) is disposed proximate to an outer edge of the die attach component 535. In this regard, the semiconductor die 510 and/or a semiconductor package incorporating the semiconductor die 510 may exhibit reduced cracking and/or delamination and increased thermal performance, as described above in connection with FIGS. 3A-4B.

As indicated above, FIGS. 5A-5K are provided as an example. Other examples may differ from what is described with respect to FIGS. 5A-5K.

FIG. 6 is a diagram of example equipment 600 used to manufacture various semiconductor packages, semiconductor dies, memory devices, or similar components described herein. In some implementations, the equipment 600 may be used to manufacture the semiconductor packages 300, 302, 400, 402, semiconductor dies 305, 405, 510, and/or components associated with the semiconductor packages 300, 302, 400, 402 and/or semiconductor dies 305, 405, 510. As shown in FIG. 6, the equipment 600 may include a packaging system 602. The packaging system 602 may include one or more devices or tooling, such as a printing machine 604, a tape roller 606, a back grinder 608, a dicing and/or drilling machine 610, a carrier 612, a die placement tool 614, a soldering tool 616, a reflow oven 618, a flux cleaner 620, a plasma chamber 622, a dispenser and/or molding tool 624, and/or a cure device 626. One or more devices may be may physically or communicatively coupled to one another. For example, one or more devices may interconnect via wired connections and/or wireless connections, such as via a bus 628. Additionally, or alternatively, one or more devices may form part of an electronics assembly manufacturing line.

The printing machine 604 may be a device capable of printing patterns in a material such as silicon, a dielectric material, a polyimide layer, or a similar material, for purposes of forming an integrated circuit or the like. In some implementations, the printing machine 604 may be a lithography device capable of printing patterns in a material to form an integrated circuit.

The tape roller 606 may be a device capable of laminating a tape (e.g., a back grinding tape) on a semiconductor wafer and/or a semiconductor die. The tape roller 606 may be capable of applying pressure to a tape as the tape is being laminated onto a wafer or a die.

The back grinder 608 may be a device capable of grinding a backside of a semiconductor wafer and/or a semiconductor die, thereby reducing a thickness of the wafer and/or a die to a desired thickness (e.g., as described above in connection with FIG. 5B). In some implementations, the back grinder 608 may be associated with a rotary table, a chuck table, and/or a grinding wheel for purposes of grinding a wafer and/or a die to a suitable thickness.

The dicing and/or drilling machine 610 may be a device capable of dicing a die, such as a microcontroller, a memory die, or other semiconductor die, from a wafer. In some implementations, the dicing and/or drilling machine 610 may include one or more dicing blades and/or one or more lasers to dice a die from the wafer. In some implementations, the dicing and/or drilling machine 610 may be associated with a chamfered dicing blade (e.g., chamfered dicing blade 506) and/or a filleted blade (e.g., filleted dicing blade 508), such as for purposes of forming a chamfered and/or rounded edge in a semiconductor die as the semiconductor die is diced from a wafer, as described above in connection with FIGS. 5A-5K. In some implementations, the dicing and/or drilling machine 610 may be a device capable of drilling through vias in a mold compound. For example, the dicing and/or drilling machine 610 may include a laser capable of drilling through vias in a mold compound.

The carrier 612 may be a device capable of supporting and/or carrying a substrate during a die and/or chip attachment process, during a compression molding process, or during a similar process. The carrier 612 may be constructed from a non-contaminating material, such as quartz, glass, or a similar material, and may be capable of withstanding high temperatures. In that regard, the carrier 612 may be capable of carrying a substrate and/or one or more die through one or more ovens, such as a reflow oven 618 and/or a cure device 626.

The die placement tool 614 may be a high-precision tool capable of placing a die onto a substrate. In some implementations, the die placement tool 614 may be capable of flipping a flip chip die during a placement process, such that an active surface of the flip chip die, which may be facing up during preliminary manufacturing steps, may face the substrate during the flip chip die placement process. In some implementations, the die placement tool 614 may include one or more sensors capable of aligning bump bonds on a die with bond pads on a substrate during a flip chip die attachment process. In some implementations, the die placement tool may be configured to place a die attach component (e.g., die attach component 315, 415) between a die a substrate, such as a DAF that couples the die to the substrate.

The soldering tool 616 may be capable of forming one or more solder connections between components of a semiconductor package. For example, the soldering tool 616 may be capable of forming wire bond connections between components of a semiconductor package by soldering wires connecting wire bond pads from one component to wire bond pads of another component. In some examples, the soldering tool 616 may be capable of applying a solder paste to between electrical contacts of electronic components, such as between electrical contacts provided on a semiconductor component and corresponding electrical contacts provided on a substrate. Additionally, or alternatively, the soldering tool 616 may be capable of applying solder or other electrically conductive material to form a portion of an electrical connection to be formed between a die and a substrate. For example, the soldering tool 616 may be capable of applying a grid of solder bumps (e.g., micro balls) to a die and/or a molded die assembly, which will align with a grid of bump pads on a substrate during a flip chip attachment process, or the like.

The reflow oven 618 may be a device capable of heating components to a suitable temperature to cause a reflow of solder or other bonding material, thereby causing the solder or similar material to melt and make an electrical connection between two components.

The flux cleaner 620 may be a device capable of removing residual flux from a soldering process. In some implementations, the flux cleaner 620 may include a heater capable of removing residual flux through a heat treatment process. Additionally, or alternatively, the flux cleaner 620 may include a nozzle or similar device capable of applying a cleaning agent to a component in order to remove residual flux therefrom.

The plasma chamber 622 may be a device capable of providing plasma treatment to component. In some implementations, the plasma chamber 622 may be capable of directly or indirectly applying a plasma stream to an area of a component, such as for purposes of preparing the area on the component for receiving an epoxy underfill, or the like.

The dispenser and/or molding tool 624 may be a device capable of dispensing a filler material around a die or similar component. In some implementations, the dispenser and/or molding tool 624 may be capable of dispensing a mold compound (e.g., an epoxy mold compound) during a compression molding process. In some implementations, the dispenser and/or molding tool 624 may include a dispensing needle capable of applying an epoxy underfill by capillary action under pressure, such as by dispensing underfill material around a periphery of a die and/or other electrical component such that the underfill material flows beneath the die and/or other electrical component and fills a space between the die and/or other electrical component and a substrate.

The cure device 626 may be a device capable of curing a material, such as a UV curable adhesive layer, a mold compound, such as an epoxy mold compound, an epoxy underfill material, an MUF material, or a similar material. In some implementations, the cure device 626 may include a UV lamp capable of irradiating a back grinding tape with UV light in order to cure an adhesive layer thereof. In some implementations, the cure device 626 may be an oven configured to heat a mold compound to a suitable curing temperature. Additionally, or alternatively, the cure device 626 may be capable of curing a mold compound via a chemical reaction, by the application of UV light, by the application of other radiation, or the like.

The number and arrangement of devices and networks shown in FIG. 6 are provided as an example. In practice, there may be additional devices, fewer devices, different devices, or differently arranged devices than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of equipment 600 may perform one or more functions described as being performed by another set of devices of equipment 600.

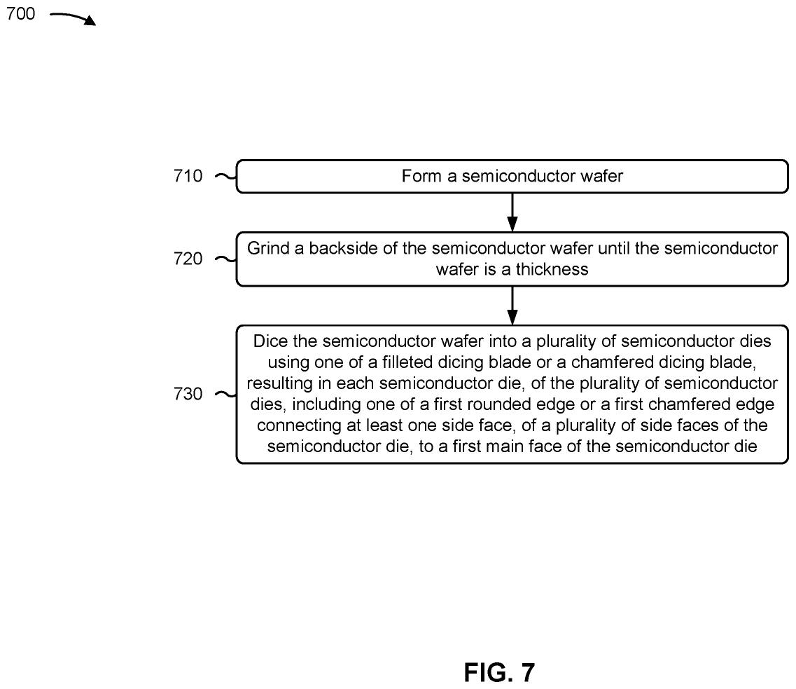

FIG. 7 is a flowchart of an example method 700 of forming a semiconductor die having a rounded or chamfered edge. In some implementations, one or more process blocks of FIG. 7 may be performed by various semiconductor manufacturing equipment, such as the semiconductor manufacturing equipment described above in connection with FIG. 6.

As shown in FIG. 7, the method 700 may include forming a semiconductor wafer (block 710). As further shown in FIG. 7, the method 700 may include grinding a backside of the semiconductor wafer until the semiconductor wafer is a thickness (block 720). As further shown in FIG. 7, the method 700 may include dicing the semiconductor wafer into a plurality of semiconductor dies using one of a filleted dicing blade or a chamfered dicing blade, resulting in each semiconductor die, of the plurality of semiconductor dies, including one of a first rounded edge or a first chamfered edge connecting at least one side face, of a plurality of side faces of the semiconductor die, to a first main face of the semiconductor die (block 730).

The method 700 may include additional aspects, such as any single aspect or any combination of aspects described below and/or in connection with one or more other methods described elsewhere herein.

In a first aspect, the method 700 includes forming, for each semiconductor die of the plurality of semiconductor dies, one of a second rounded edge or a second chamfered edge connecting the at least one side face to a second main face of the semiconductor die.

In a second aspect, alone or in combination with the first aspect, the method 700 includes dicing the semiconductor wafer into the plurality of semiconductor dies using the chamfered dicing blade, resulting in each semiconductor die, of the plurality of semiconductor dies, including the first chamfered edge, wherein a leg length of the first chamfered edge is greater than one-twentieth of the thickness and less than one-half of the thickness.

In a third aspect, alone or in combination with one or more of the first and second aspects, the method 700 includes dicing the semiconductor wafer into the plurality of semiconductor dies using the filleted dicing blade, resulting in each semiconductor die, of the plurality of semiconductor dies, including the first rounded edge, wherein a radius of curvature of the first rounded edge is greater than one-twentieth of the thickness and less than one-half of the thickness.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the semiconductor die 305, semiconductor die 405, and/or semiconductor die 510, an integrated assembly that includes the semiconductor die 305, semiconductor die 405, and/or semiconductor die 510, any part described herein of the semiconductor die 305, semiconductor die 405, and/or semiconductor die 510, and/or any part described herein of an integrated assembly that includes the semiconductor die 305, semiconductor die 405, and/or semiconductor die 510. For example, the method 700 may include forming one or more of the chamfered edge 325, chamfered edge 345, rounded edge 425, rounded edge 445, chamfered edge 512, and/or rounded edge 514.

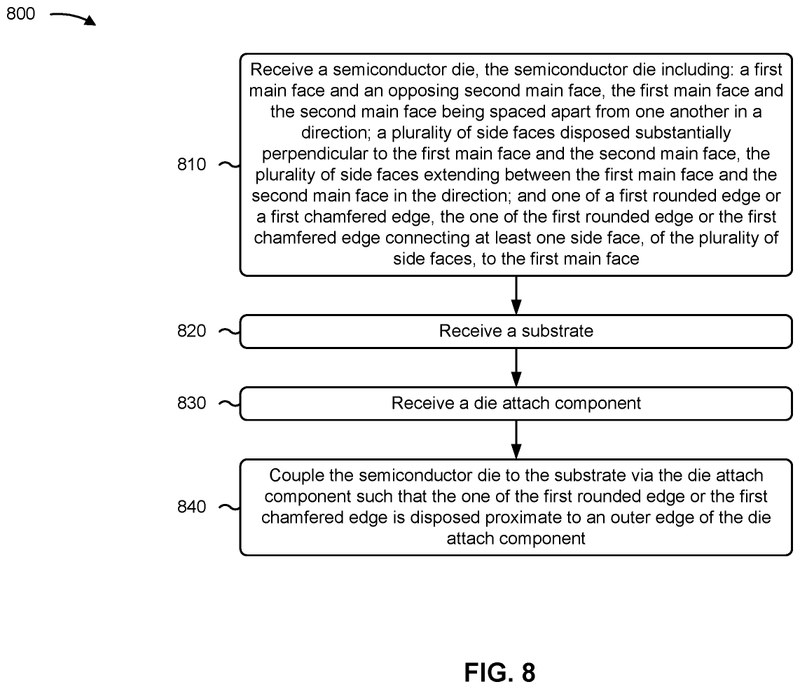

FIG. 8 is a flowchart of an example method 800 of forming an integrated assembly or memory device having a semiconductor die with a rounded or chamfered edge. In some implementations, one or more process blocks of FIG. 8 may be performed by various semiconductor manufacturing equipment, such as the semiconductor manufacturing equipment described above in connection with FIG. 6.

As shown in FIG. 8, the method 800 may include receiving a semiconductor die, the semiconductor die including: a first main face and an opposing second main face, the first main face and the second main face being spaced apart from one another in a direction; a plurality of side faces disposed substantially perpendicular to the first main face and the second main face, the plurality of side faces extending between the first main face and the second main face in the direction; and one of a first rounded edge or a first chamfered edge, the one of the first rounded edge or the first chamfered edge connecting at least one side face, of the plurality of side faces, to the first main face (block 810). As further shown in FIG. 8, the method 800 may include receiving a substrate (block 820). As further shown in FIG. 8, the method 800 may include receiving a die attach component (block 830). As further shown in FIG. 8, the method 800 may include coupling the semiconductor die to the substrate via the die attach component such that the one of the first rounded edge or the first chamfered edge is disposed proximate to an outer edge of the die attach component (block 840).

The method 800 may include additional aspects, such as any single aspect or any combination of aspects described below and/or in connection with one or more other methods described elsewhere herein.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the semiconductor package 300, the semiconductor package 302, the semiconductor package 400, and/or the semiconductor package 402, an integrated assembly that includes the semiconductor package 300, the semiconductor package 302, the semiconductor package 400, and/or the semiconductor package 402, any part described herein of the semiconductor package 300, the semiconductor package 302, the semiconductor package 400, and/or the semiconductor package 402, and/or any part described herein of an integrated assembly that includes the semiconductor package 300, the semiconductor package 302, the semiconductor package 400, and/or the semiconductor package 402. For example, the method 800 may include forming one or more of the semiconductor die 305 and/or the semiconductor die 405.

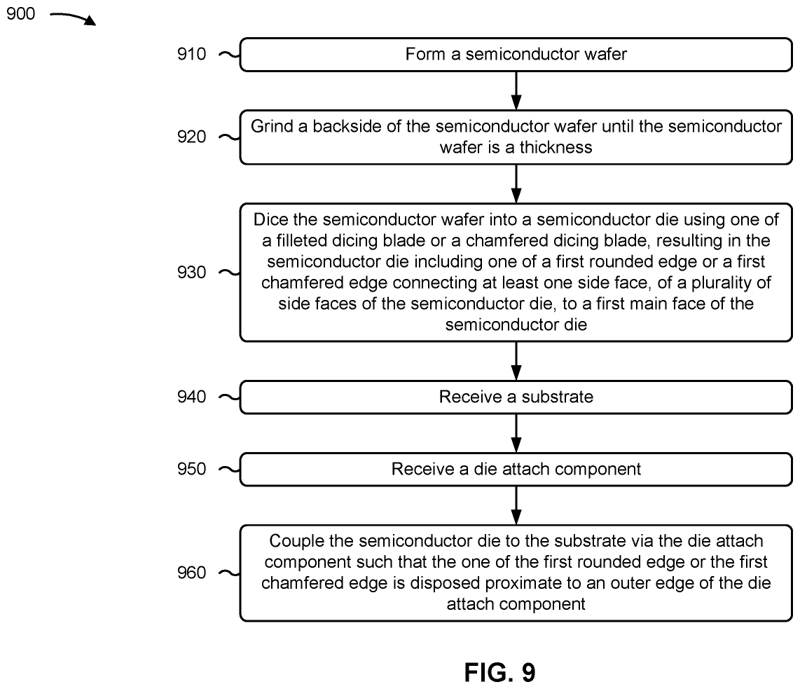

FIG. 9 is a flowchart of an example method 900 of forming an integrated assembly or memory device having a semiconductor die with a rounded or chamfered edge. In some implementations, one or more process blocks of FIG. 9 may be performed by various semiconductor manufacturing equipment, such as the semiconductor manufacturing equipment described above in connection with FIG. 6.

As shown in FIG. 9, the method 900 may include forming a semiconductor wafer (block 910). As further shown in FIG. 9, the method 900 may include grinding a backside of the semiconductor wafer until the semiconductor wafer is a thickness (block 920). As further shown in FIG. 9, the method 900 may include dicing the semiconductor wafer into a semiconductor die using one of a filleted dicing blade or a chamfered dicing blade, resulting in the semiconductor die including one of a first rounded edge or a first chamfered edge connecting at least one side face, of a plurality of side faces of the semiconductor die, to a first main face of the semiconductor die (block 930). As further shown in FIG. 9, the method 900 may include receiving a substrate (block 940). As further shown in FIG. 9, the method 900 may include receiving a die attach component (block 950). As further shown in FIG. 9, the method 900 may include coupling the semiconductor die to the substrate via the die attach component such that the one of the first rounded edge or the first chamfered edge is disposed proximate to an outer edge of the die attach component (block 960).

The method 900 may include additional aspects, such as any single aspect or any combination of aspects described below and/or in connection with one or more other methods described elsewhere herein.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the semiconductor package 300, the semiconductor package 302, the semiconductor package 400, and/or the semiconductor package 402, an integrated assembly that includes the semiconductor package 300, the semiconductor package 302, the semiconductor package 400, and/or the semiconductor package 402, any part described herein of the semiconductor package 300, the semiconductor package 302, the semiconductor package 400, and/or the semiconductor package 402, and/or any part described herein of an integrated assembly that includes the semiconductor package 300, the semiconductor package 302, the semiconductor package 400, and/or the semiconductor package 402. For example, the method 900 may include forming one or more of the semiconductor die 305 and/or the semiconductor die 405.

In some implementations, a semiconductor die includes a first main face and an opposing second main face, the first main face and the second main face being spaced apart from one another in a direction; a plurality of side faces disposed substantially perpendicular to the first main face and the second main face, the plurality of side faces extending between the first main face and the second main face in the direction; and one of a first rounded edge or a first chamfered edge, the one of the first rounded edge or the first chamfered edge connecting at least one side face, of the plurality of side faces, to the first main face.

In some implementations, a semiconductor device assembly includes a substrate; and a semiconductor die coupled to the substrate, the semiconductor die including: a first main face facing the substrate and an opposing second main face facing away from the substrate, the first main face and the second main face being spaced apart from one another in a first direction; a plurality of side faces disposed substantially perpendicular to the first main face and the second main face, the plurality of side faces extending between the first main face and the second main face in the first direction; and one of a first rounded edge or a first chamfered edge, the one of the first rounded edge or the first chamfered edge connecting at least one side face, of the plurality of side faces, to the first main face.

In some implementations, a method includes forming a semiconductor wafer; grinding a backside of the semiconductor wafer until the semiconductor wafer is a thickness; and dicing the semiconductor wafer into a plurality of semiconductor dies using one of a filleted dicing blade or a chamfered dicing blade, resulting in each semiconductor die, of the plurality of semiconductor dies, including one of a first rounded edge or a first chamfered edge connecting at least one side face, of a plurality of side faces of the semiconductor die, to a first main face of the semiconductor die.

In some implementations, a method includes receiving a semiconductor die, the semiconductor die including: a first main face and an opposing second main face, the first main face and the second main face being spaced apart from one another in a direction; a plurality of side faces disposed substantially perpendicular to the first main face and the second main face, the plurality of side faces extending between the first main face and the second main face in the direction; and one of a first rounded edge or a first chamfered edge, the one of the first rounded edge or the first chamfered edge connecting at least one side face, of the plurality of side faces, to the first main face; receiving a substrate; receiving a die attach component; and coupling the semiconductor die to the substrate via the die attach component such that the one of the first rounded edge or the first chamfered edge is disposed proximate to an outer edge of the die attach component.

In some implementations, a method includes forming a semiconductor wafer; grinding a backside of the semiconductor wafer until the semiconductor wafer is a thickness; dicing the semiconductor wafer into a semiconductor die using one of a filleted dicing blade or a chamfered dicing blade, resulting in the semiconductor die including one of a first rounded edge or a first chamfered edge connecting at least one side face, of a plurality of side faces of the semiconductor die, to a first main face of the semiconductor die; receiving a substrate; receiving a die attach component; and coupling the semiconductor die to the substrate via the die attach component such that the one of the first rounded edge or the first chamfered edge is disposed proximate to an outer edge of the die attach component.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor die, comprising:
a first main face and an opposing second main face, the first main face and the second main face being spaced apart from one another in a direction;
a plurality of side faces disposed substantially perpendicular to the first main face and the second main face, the plurality of side faces extending between the first main face and the second main face in the direction; and
one of a first rounded edge or a first chamfered edge, the one of the first rounded edge or the first chamfered edge connecting at least one side face, of the plurality of side faces, to the first main face.

2. The semiconductor die of claim 1, further comprising one of a second rounded edge or a second chamfered edge, the one of the second rounded edge or the second chamfered edge connecting the at least one side face to the second main face.

3. The semiconductor die of claim 1, wherein the semiconductor die includes the first chamfered edge, wherein a leg length of the first chamfered edge is greater than one-twentieth of a thickness of the semiconductor die and less than one-half of the thickness of the semiconductor die, and wherein the thickness of the semiconductor die corresponds to a distance, in the direction, between the first main face and the second main face.

4. The semiconductor die of claim 1, wherein the semiconductor die includes the first rounded edge, wherein a radius of curvature of the first rounded edge is greater than one-twentieth of a thickness of the semiconductor die and less than one-half of the thickness of the semiconductor die, and wherein the thickness of the semiconductor die corresponds to a distance, in the direction, between the first main face and the second main face.

5. The semiconductor die of claim 1, wherein the one of the first rounded edge or the first chamfered edge extends around an entire perimeter of the first main face.

6. The semiconductor die of claim 5, further comprising one of a second rounded edge or a second chamfered edge, the one of the second rounded edge or the second chamfered edge connecting the at least one side face to the second main face, wherein the one of the second rounded edge or the second chamfered edge extends around an entire perimeter of the second main face.

7. The semiconductor die of claim 1, wherein an outer perimeter of the semiconductor die is larger than a perimeter of the first main face.

8. A semiconductor device assembly, comprising:
a substrate; and
a semiconductor die coupled to the substrate, the semiconductor die including:
a first main face facing the substrate and an opposing second main face facing away from the substrate, the first main face and the second main face being spaced apart from one another in a first direction;
a plurality of side faces disposed substantially perpendicular to the first main face and the second main face, the plurality of side faces extending between the first main face and the second main face in the first direction; and
one of a first rounded edge or a first chamfered edge, the one of the first rounded edge or the first chamfered edge connecting at least one side face, of the plurality of side faces, to the first main face.

9. The semiconductor device assembly of claim 8, further comprising a die attach component coupling the semiconductor die to the substrate, wherein the one of the first rounded edge or the first chamfered edge extends, in a second direction perpendicular to the first direction, beyond an outer perimeter of the die attach component.

10. The semiconductor device assembly of claim 8, further comprising a die attach component coupling disposed between the first main face and the substrate, wherein the one of the first rounded edge or the first chamfered edge is disposed proximate to an outer edge of the die attach component.

11. The semiconductor device assembly of claim 8, wherein the semiconductor die further includes one of a second rounded edge or a second chamfered edge, the one of the second rounded edge or the second chamfered edge connecting the at least one side face to the second main face.

12. The semiconductor device assembly of claim 8, wherein the semiconductor die includes the first chamfered edge, wherein a leg length of the first chamfered edge is greater than one-twentieth of a thickness of the semiconductor die and less than one-half of the thickness of the semiconductor die, and wherein the thickness of the semiconductor die corresponds to a distance, in the first direction, between the first main face and the second main face.

13. The semiconductor device assembly of claim 8, wherein the semiconductor die includes the first rounded edge, wherein a radius of curvature of the first rounded edge is greater than one-twentieth of a thickness of the semiconductor die and less than one-half of the thickness of the semiconductor die, and wherein the thickness of the semiconductor die corresponds to a distance, in the first direction, between the first main face and the second main face.

14. The semiconductor device assembly of claim 8, wherein the one of the first rounded edge or the first chamfered edge extends around an entire perimeter of the first main face.

15. The semiconductor device assembly of claim 14, wherein the semiconductor die further includes one of a second rounded edge or a second chamfered edge, the one of the second rounded edge or the second chamfered edge connecting the at least one side face to the second main face, and wherein the one of the second rounded edge or the second chamfered edge extends around an entire perimeter of the second main face.

16. The semiconductor device assembly of claim 8, wherein an outer perimeter of the semiconductor die is larger than a perimeter of the first main face.

17. A method, comprising:
forming a semiconductor wafer;
grinding a backside of the semiconductor wafer until the semiconductor wafer is a thickness; and
dicing the semiconductor wafer into a plurality of semiconductor dies using one of a filleted dicing blade or a chamfered dicing blade, resulting in each semiconductor die, of the plurality of semiconductor dies, including one of a first rounded edge or a first chamfered edge connecting at least one side face, of a plurality of side faces of the semiconductor die, to a first main face of the semiconductor die.

18. The method of claim 17, further comprising forming, for each semiconductor die of the plurality of semiconductor dies, one of a second rounded edge or a second chamfered edge connecting the at least one side face to a second main face of the semiconductor die.

19. The method of claim 17, further comprising dicing the semiconductor wafer into the plurality of semiconductor dies using the chamfered dicing blade, resulting in each semiconductor die, of the plurality of semiconductor dies, including the first chamfered edge, wherein a leg length of the first chamfered edge is greater than one-twentieth of the thickness and less than one-half of the thickness.

20. The method of claim 17, further comprising dicing the semiconductor wafer into the plurality of semiconductor dies using the filleted dicing blade, resulting in each semiconductor die, of the plurality of semiconductor dies, including the first rounded edge, wherein a radius of curvature of the first rounded edge is greater than one-twentieth of the thickness and less than one-half of the thickness.
